(19) United States
(12) Patent Application Publication
(10) Pub. No.: US 2013/0078815 A1
(43) Pub. Date: Mar. 28, 2013

(54) METHOD FOR FORMING SEMICONDUCTOR STRUCTURE WITH REDUCED LINE EDGE ROUGHNESS

(71) Applicants: Chang-Ming Wu, Taoyuan County (TW); Yi-Nan Chen, Taoyuan County (TW); Hsien-Wen Liu, Taoyuan County (TW)

(72) Inventors: Chang-Ming Wu, Taoyuan County (TW); Yi-Nan Chen, Taoyuan County (TW); Hsien-Wen Liu, Taoyuan County (TW)

(73) Assignee: NANYA TECHNOLOGY CORPORATION, Taoyuan (TW)

(21) Appl. No.: 13/244,013

(22) Filed: Sep. 23, 2011

(51) Int. Cl. H01L 21/3065

(52) U.S. Cl. 438/714; 257/E21.218

(57) ABSTRACT

A method for forming a semiconductor structure with reduced line edge roughness is provided, including: providing a device layer with a patterned photoresist layer formed thereon; and performing a plasma etching process to pattern the device layer with the patterned photoresist layer formed thereon, forming a patterned device layer, wherein the plasma etching process is operated under a continuous on-stage voltage provided with a relative higher frequency and an on-off stage voltage with pulsing modulation provided with a relative lower frequency.

### BACKGROUND OF THE INVENTION

1. Field of the Invention

The invention relates to semiconductor fabrication, and in particularly to a method for forming a semiconductor structure with reduced line edge roughness (LER).

2. Description of the Related Art

Generally, photolithography techniques are applied in the process of manufacturing semiconductor devices. Photolithography techniques are composed of the following steps. First, a photoresist material is applied on laminated thin film layers disposed on a semiconductor substrate, which is exposed to ultra violet rays in an exposure apparatus. Thereby, the circuit pattern of a photoresist mask is transferred onto the photoresist material via exposure, which is then developed. Thereafter, the desired circuit pattern is formed via an etching process using plasma.

Furthermore, a plasma processing apparatus is generally used for the etching process for transferring the developed photoresist circuit pattern to the laminated thin film disposed below thereof. The plasma processing apparatus is composed of, for example, a vacuum processing chamber, a gas supply unit connected thereto, a vacuum unit for maintaining the pressure within the vacuum processing chamber to a desirable value, an electrode on which the material is to be processed, or semiconductor substrate, is placed, and a plasma generating means for generating plasma in the vacuum processing chamber, wherein the etching of the material to be processed placed on the substrate-placing electrode is performed by generating plasma from the processing gas supplied into the vacuum processing chamber through a shower plate or the like via a plasma generating means.

Because the photoresist is used to form a circuit pattern on the semiconductor devices, the integrity of the photoresist must be maintained throughout the lithography process. That is, any flaw or structural defect which is present on a patterned photoresist circuit pattern will be indelibly transferred to underlying layers during a sequential etching process wherein the patterned photoresist circuit pattern is employed.

One example of an undesirable structural defect is line edge roughness (LER). LER refers to the variations on the sidewalls of features which may originate from LER in the patterned photoresist circuit pattern. LER appearance in fabricated structures can occur as a result of damage to the patterned photoresist circuit pattern during, for example, the plasma etching process, as illustrated in the partially fabricated semiconductor structure 10 in FIG. 1. The semiconductor structure 10 includes a silicon substrate 20, a dielectric layer 30, and a patterned photoresist layer 40 formed over the dielectric layer 30. As shown, plasma etchants (not shown) employed to bombard exposed portions of the dielectric layer 30 through a patterned photoresist layer 40 inevitably attack the relatively soft photoresist material at the sidewall 50 of the photoresist layer 40. In addition to removing exposed portions of the dielectric layer, the energetic and reactive plasma species may alter the properties of the photoresist material of the photoresist layer 40, thus leading to line edge roughness (LER) 60 in the patterned photoresist layer 40. Therefore, after the plasma etching process, the patterned photoresist layer 40 with the undesired line edge roughness (LER) 60 is indelibly transferred to the underlying dielectric layer 30 such that circuit patterns with undesired LER issues are also formed in the dielectric layer 30, thereby affecting reliability of a semiconductor device comprising the circuit patterns formed in the dielectric layer.

The above plasma effects can be more serious for 193 nm photoresists, which have less etch resistance than photoresists used at higher wavelengths such as 248 nm, 365 nm, etc. The condition may even worsen for wavelengths below 193 nm, such as 157 nm photoresists.

Moreover, as feature size decreases, line-edge roughness can interfere with accurate metrology and adversely affect device performance.

### BRIEF SUMMARY OF THE INVENTION

Therefore, a method for forming a semiconductor structure with reduced line edge roughness (LER) is provided.

An exemplary method for forming a semiconductor structure with reduced line edge roughness comprises: providing a device layer with a patterned photoresist layer formed thereon; and performing a plasma etching process to pattern the device layer with the patterned photoresist layer formed thereon, forming a patterned device layer, wherein the plasma etching process is operated under a continuous on-stage voltage provided with a relative higher frequency and an on-off stage voltage with pulsing modulation provided with a relative lower frequency.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic cross section of a partially fabricated semiconductor device in the prior art having line edge roughness (LER) issues;

FIG. 2 is a flowchart showing a method for forming a semiconductor structure with reduced line edge roughness (LER) issues according to an embodiment of the invention;

FIGS. 3 and 5 are schematic cross sections showing various stages in the method for forming the semiconductor structure with reduced line edge roughness (LER) issues shown in FIG. 2; and

FIGS. 4a and 4b are schematic diagrams showing power pulsing modulation in a plasma etching process in the method for forming the semiconductor structure with reduced line edge roughness (LER) issues shown in FIG. 2.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

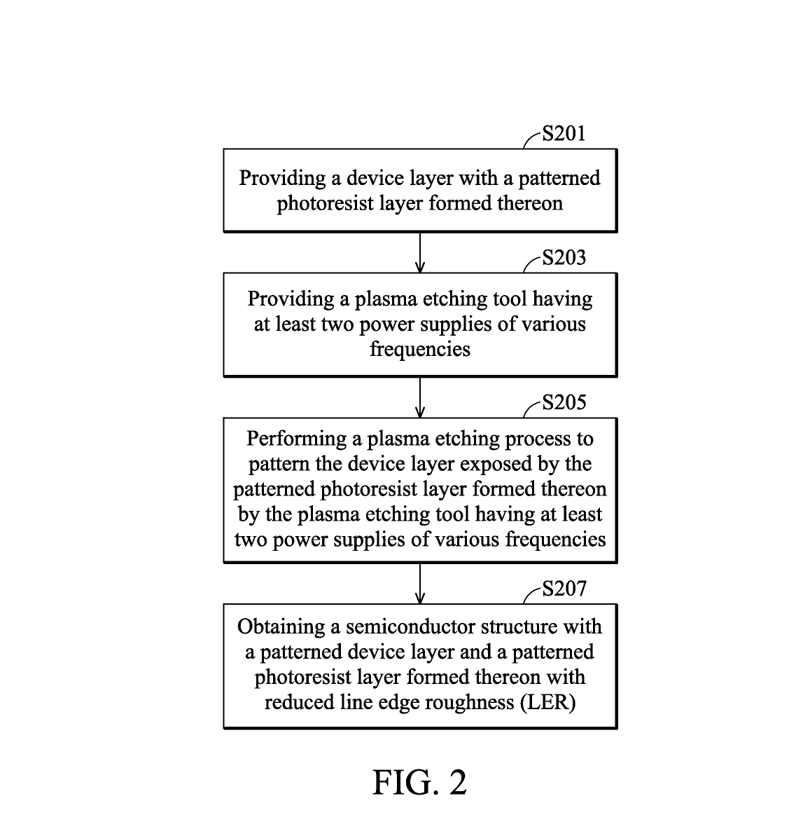

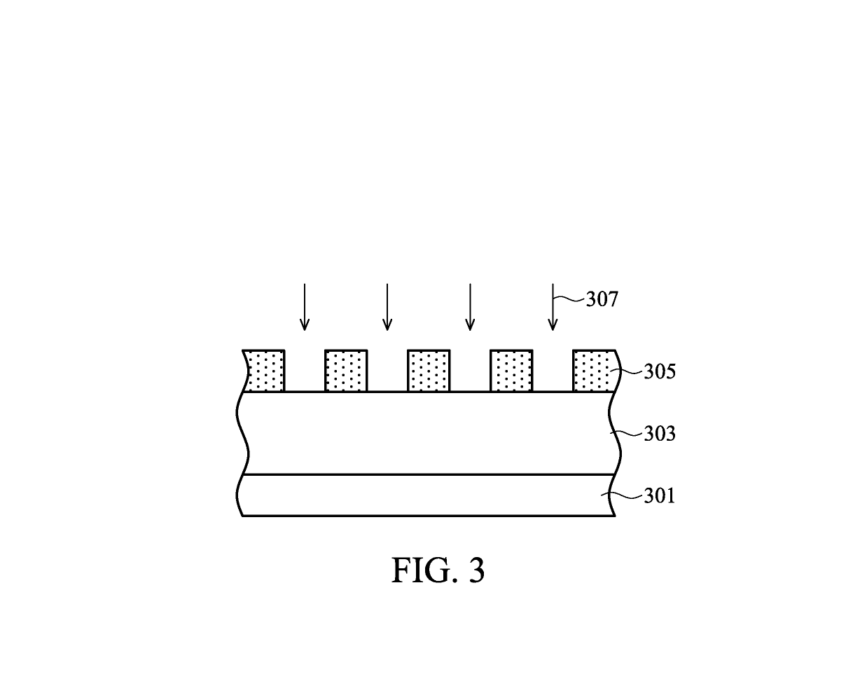

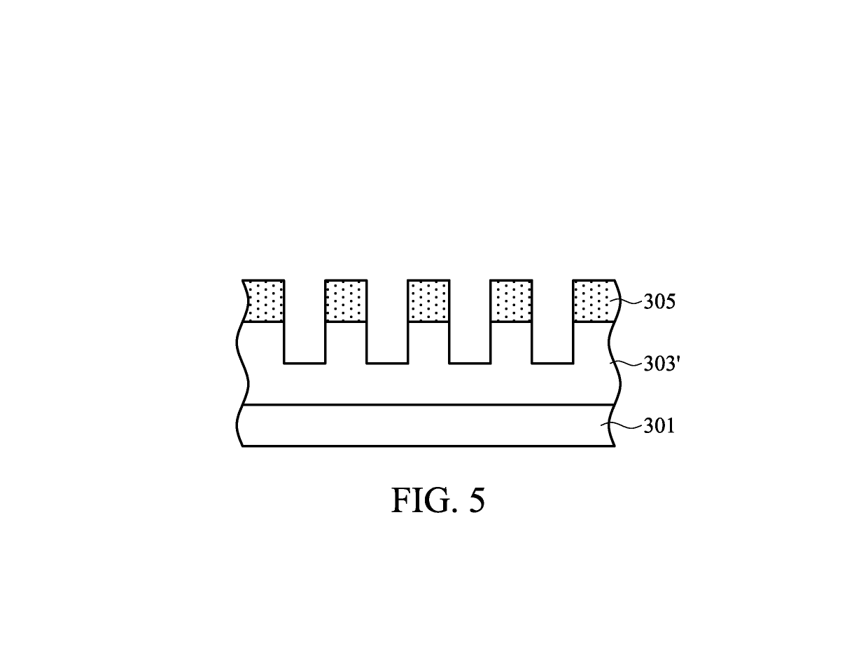

FIG. 2 is a flowchart showing an exemplary method for forming a semiconductor structure with reduced line edge roughness (LER) issues, and FIGS. 3 and 5 are schematic cross sections showing various stages in the exemplary method for forming the semiconductor structure with reduced line edge roughness (LER) issues shown in FIG. 2.

As shown in FIG. 2 and FIG. 3, the method begins in step S201, wherein a substrate 301 having a device layer 303 with a patterned photoresist layer 305 for forming a circuit pattern formed thereon is provided. The substrate 301 may comprise semiconductor materials such as silicon. The device layer 303 may comprise materials such as semiconductor, metal or dielectric materials typically used for forming a semiconductor device. The patterned photoresist layer 305 may comprise known photoresist materials for a 157 nm, 193 nm, 248 nm, or 365 nm photolithography process, which were previously patterned by a photolithography process (not shown).

As shown in FIG. 2 and FIG. 3, in step S203, a plasma etching tool (not shown) having at least two power supplies of various frequencies is then provided. The plasma etching tool here can be, for example, an inductively coupled plasma (ICP) etching tool or a capacitor coupled plasma (CCP) etching tool, and the at least power supplies of various frequencies may comprise power supplies operated in a frequency of, for example, 2 MHz or 13.56 MHz.

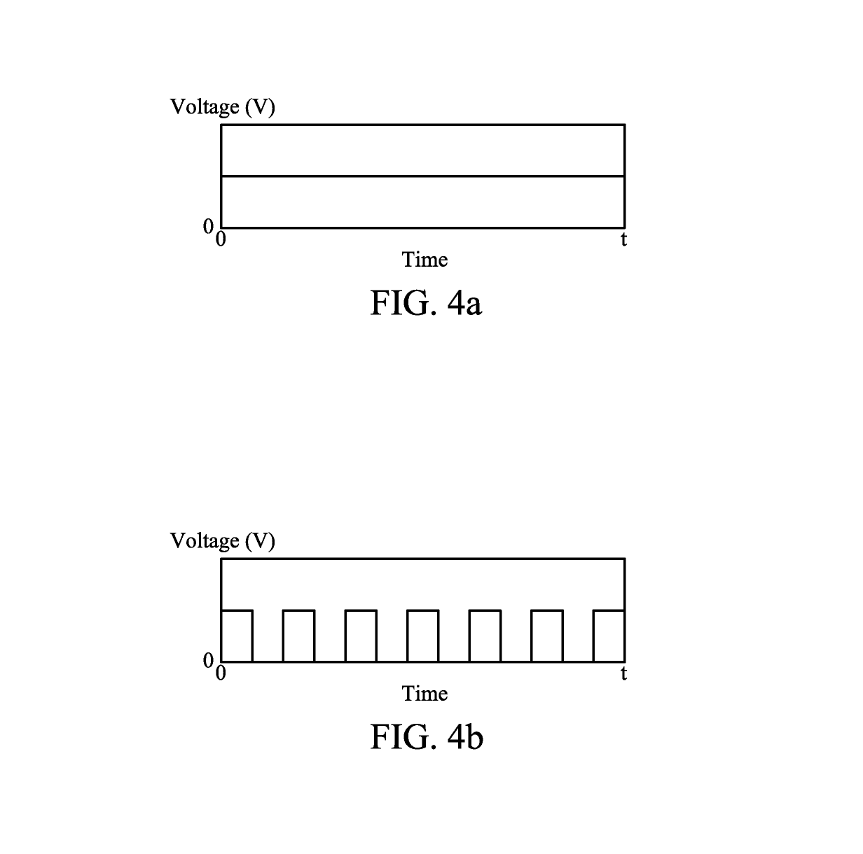

As shown in FIG. 2 and FIG. 3, in step 205, a plasma etching process 307 is then performed to pattern the device layer 303 exposed by the patterned photoresist layer 305 formed thereon by the plasma etching tool having at least two power supplies of various frequencies provided in step S203. Processing gases (not shown) used in the plasma etching process 307 may depend on the materials used in the device layer 303 and are not described here in detail. In one embodiment, one of at least two power supplies of a relative higher frequency in the plasma etching tool is operated under a frequency of, for example 13.56 MHz and under a continuous on-stage voltage during the plasma etching process 307, as shown in FIG. 4a. At the same time, one of the at least two power supplies of a relative lower frequency in the plasma etching tool is operated under a frequency of, for example, 2 MHz and under an on-off stage voltage with pulsing modulation during the plasma etching process 307, as shown in FIG. 4b. As shown in FIG. 4b, an on-time interval of the on-off stage voltage is less than 1E-6 seconds, and the power supplies of a relative lower frequency show duty ratios (defined as overall on time/overall process time) greater than 60% in the plasma etching process 307.

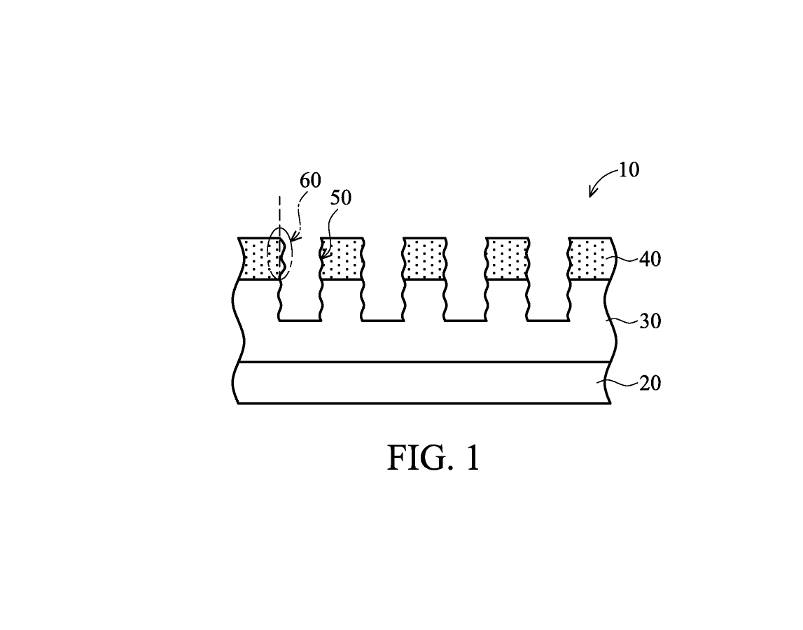

As shown in FIG. 2 and FIG. 5, in step S207, after the plasma etching process 207, a partially fabricated semiconductor structure with a patterned device layer 303′ and the patterned photoresist layer 305 formed thereon with reduced line edge roughness (LER) issues is illustrated. The partially fabricated semiconductor structure shown in FIG. 5 is formed with reduced line edge roughness issues in both the patterned photoresist layer 305 and the patterned device layer 303′ when compared with a partially fabricated semiconductor structure (not shown) similar with that shown in FIG. 1 which may formed by a modified plasma etching process using the same plasma etching tool where all the power supplies of various frequencies remained at on-stage voltages during the plasma etching process. As shown in FIG. 5, since the patterned photoresist layer 305 is formed with reduced line edge roughness issues such that the circuit pattern of the patterned photoresist layer 305 can be perfectly transferred to the underlying device layer 303 without any flaw or structural defect therein after the plasma etching process 307. Therefore, circuit pattern with reduced LER issues can be formed in the patterned device layer 303′, thereby assuring reliability of a semiconductor device comprising the patterned device layer 303′. In one embodiment, about an amount of 30% to 40% reduction of a 3 sigma deviation of a line edge roughness (LER) can be achieved in the patterned device layer 303′ by the above method. Therefore, the line edge roughness (LER) issue can be reduced or even eliminated and a device performance of the formed semiconductor device will not be adversely affected.

Next, the patterned photoresist layer 305 can be removed and other subsequent processes can be performed on the patterned device layer 303′ to form a semiconductor device over the substrate 301.

### EXAMPLE 1

A semiconductor device similar with that shown in FIG. 3 was provided. The semiconductor device was formed with a silicon oxide layer and a patterned photoresist layer formed thereover. The patterned photoresist layer was formed with a width of about 40 nm. Next, a plasma etching was performed to etch the silicon oxide layer by an inductively coupled plasma (ICP) etching tool, using etchants comprising CHF₃, O₂ and argon (Ar). The (ICP) etching tool comprises two power supplies operated in a frequency of 2 MHz and 13.56 MHz, respectively, and the power supply of the frequency of 13.56 MHz in the plasma etching tool was operated under a continuous on-stage voltage during the plasma etching and the power supply of the lower frequency of the 2 MHz frequency in the plasma etching tool was operated under an on-off stage voltage with pulsing modulation during the plasma etching process. An on-time interval of the on-off stage voltage was less than 1E-6 seconds, and the power supplies of the 2 MHz frequency showed duty ratios (defined as overall on time/overall process time) greater than 80% in the plasma etching. After the plasma etching, the patterned resist layer was removed and a patterned silicon oxide layer of a line width of about 40 nm was formed, and a 3 sigma deviation of a line edge roughness (LER) of the patterned silicon oxide layer of about 1.73-1.75 nm was measured.

### Comparative Example 1

A semiconductor device similar with that shown in FIG. 3 was provided. The semiconductor device was formed with a silicon oxide layer and a patterned photoresist layer formed thereover. The patterned photoresist layer was formed with a width of about 40 nm. Next, a plasma etching was performed to etch the silicon oxide layer by an inductively coupled plasma (ICP) etching tool, using etchants comprising CHF₃, O₂ and argon (Ar). The (ICP) etching tool comprises two power supplies operated in a frequency of 2 MHz and 13.56 MHz, respectively, and both of the two power supplies of the frequency of 2 MHz and 13.56 MHz in the plasma etching tool were operated under a continuous on-stage voltage during the plasma etching. After the plasma etching, the patterned resist layer was removed and a patterned silicon oxide layer of a line width of about 40 nm was formed, and a 3 sigma deviation of a line edge roughness (LER) of the patterned silicon oxide layer of about 2.76-2.83 nm was measured.

TABLE 1

| | 3-sigma deviation of line edge roughness |
|---|---|
| | (LER) deviation in the patterned oxide layer |
| Comparative Example 1 | 2.76-2.83 nm |
| Example | 1.73-1.75 nm |
| reduction of 3-sigma | 37%-39% |
| deviation of LER (%) | |

As shown in table 1, an amount of about 37% to 39% of reduction of a line width roughness (LWR) of the patterned silicon oxide layer was obtained by performing the plasma etching using pulsing modulation described in the embodiment 1. Therefore, the line edge roughness (LER) issue can be reduced or even eliminated in the patterned silicon oxide layer and a device performance of the formed semiconductor device will not be adversely affected.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a semiconductor structure with reduced line edge roughness (LER), comprising
providing a device layer with a patterned photoresist layer formed thereon; and
performing a plasma etching process to pattern the device layer with the patterned photoresist layer formed thereon, forming a patterned device layer, wherein the plasma etching process is operated under a continuous on-stage voltage provided with a relative higher frequency and an on-off stage voltage with pulsing modulation provided with a relative lower frequency.

2. The method as claimed in claim 1, wherein the plasma etching process is performed by a plasma etching tool having at least two power supplies of various frequencies, and one of the at least two power supplies of a relative higher frequency provides the continuous on-stage voltage with the relative higher frequency and one of the at least two power supplies of a relative lower frequency provides the on-off stage voltage with pulsing modulation with the relative lower frequency.

3. The method as claimed in claim 2, wherein the one of the at least two power supplies of a relative higher frequency is operated under a frequency of 13.56 MHz.

4. The method as claimed in claim 2, wherein the one of the at least two power supplies of a relative lower frequency is operated under a frequency of 2 MHz.

5. The method as claimed in claim 1, wherein the device layer comprises semiconductor materials, dielectric materials or metal materials.

6. The method as claimed in claim 1, wherein an on-time interval of the on-off stage voltage is less than 1E-6 seconds.

7. The method as claimed in claim 2, wherein the plasma etching tool is an inductively coupled plasma (ICP) etching tool or a capacitor coupled plasma (CCP) etching tool.

8. The method as claimed in claim 2, wherein the one of the at least two power supplies of a relative lower frequency shows a duty ratio greater than 60%.

9. The method as claimed in claim 1, wherein a 3 sigma deviation of a line edge roughness of the patterned device layer is reduced.

10. The method as claimed in claim 1, further comprising removing the patterned photoresist layer after formation of the patterned device layer.
